(19) United States
(12) Patent Application Publication
(10) Pub. No.: US 2025/0201438 A1
(43) Pub. Date: Jun. 19, 2025

(54) THIN-FILM LIQUID METAL ELECTRODE, ITS FABRICATING METHOD USING SEQUENTIAL DEPOSITION AND STRETCHABLE ELECTRONIC DEVICE USING THE ELECTRODE FABRICATED THEREFROM

(71) Applicant: Korea Advanced Institute of Science and Technology, Daejeon (KR)

(72) Inventors: Jung-Yong Lee, Daejeon (KR); Seungseok Han, Daejeon (KR)

(73) Assignee: Korea Advanced Institute of Science and Technology, Daejeon (KR)

(21) Appl. No.: 18/440,006

(22) Filed: Feb. 13, 2024

(30) Foreign Application Priority Data
Dec. 13, 2023 (KR) 10-2023-0018876

(51) Int. Cl. H01B 5/14; C23C 14/02; C23C 14/20; C23C 14/24; C23C 14/58; H01B 1/02

(52) U.S. Cl. CPC H01B 5/14; C23C 14/021; C23C 14/20; C23C 14/24; C23C 14/5853; H01B 1/02

(57) ABSTRACT

Provided are a thin-film liquid metal electrode, a method of fabricating the same using a sequential deposition, and a stretchable electronic device using the electrode fabricated therefrom. The thin-film liquid metal electrode may be applied to various application fields, such as a solar cell, a display, a biosensor, and a flexible/stretchable device using the thin-film liquid metal electrode by providing the thin-film liquid metal electrode in which at least two types of liquid metal nanoclusters are sequentially over-layered with an oxide film in therebetween and deposited as thin films on a surface-treated stretchable substrate in an over-layered structure, by fabricating the liquid metal nanoclusters in a no-direct contact structure, and by implementing negative piezoresistivity (NPR) property in which resistance decreases up to 85% during first 50% stretching since an additional electrical path is generated between two liquid metal nanoclusters as the oxide film is ruptured due to mechanical deformation.

### CROSS-REFERENCE TO RELATED APPLICATION(S)

This application claims the priority benefit of Korean Patent Application No. 10-2023-0018876, filed on Feb. 13, 2023, in the Korean Intellectual Property Office, the disclosure of which is incorporated herein by reference.

### BACKGROUND

### 1. Field of the Invention

The present invention relates to a thin-film liquid metal electrode, a method of fabricating the same using a sequential deposition, and a stretchable electronic device using an electrode fabricated therefrom, and more particularly, to a thin-film liquid metal electrode that implements negative piezoresistivity (NPR) property in which resistance decreases up to 85% during first 50% stretching by providing a thin-film liquid metal electrode in which at least two types of liquid metal nanoclusters are sequentially over-layered with an oxide film in therebetween and deposited on a surface-treated stretchable substrate in an over-layered structure, by fabricating the at least two types of liquid metal nanoclusters in a no-direct contact structure, and by generating an additional electrical path between two liquid metal nanoclusters as the oxide film is ruptured due to mechanical deformation, and a method of fabricating the same using a sequential deposition, and a stretchable electronic device using an electrode fabricated therefrom.

### 2. Description of the Related Art

Stretchable wiring technology and its application are key to the bio industry and are technical field with high growth potential. There are largely three methods to implement such stretchable wiring: a wavy and buckling structure corresponding to deformation through surface wrinkles, an island-connection that connects rigid elements with flexible wiring, and an intrinsic material.

The former two implementation methods have issues, such as complexity of a process itself and incompatibility with an existing process and also need an extra space for forming wrinkles and connections compared to a single device.

Therefore, research on intrinsic materials free from the above issues is actively conducted, but metal nanowire, graphene, and poly (3,4-ethylenedioxythiophene) polystyrene sulfonate (PEDOT:PSS) have relatively low stretchability compared to other methods. To solve this, development of a liquid metal electrode is actively ongoing by using eutectic gallium indium (EGaln) including indium and gallium as a promising stretchable material.

For example, Patent Document 1 provides a liquid metal electrode including a liquid metal, including a conductive portion formed in a predetermined shape and of which one end is in interfacing contact with a surface of a substrate and a polymer, and including a bonding portion coupled to the surface of the substrate while wrapping a non-contact outer surface that is not in contact with the substrate at the one end of the conductive portion and to bond the conductive portion to the surface of the substrate, and a fabricating method thereof forms an electrode by applying the liquid metal (e.g., EGaIn) on the substrate using a syringe.

However, a liquid metal electrode fabricated with this method is not suitable for microscale and nanoscale processes due to its thickness and line width are determined by the syringe and it is impossible to control the thickness and electrical property.

Patent Document 2 relates to a liquid metal-based fabricating method and describes a method of forming a pattern using a self-assembled monolayer (SAM) on the surface.

Patent Document 3 relates to a liquid metal circuit device and a control method thereof and a method of fabricating a microchannel to form a liquid circuit and injecting a liquid metal into the channel. More particularly, disclosed is a method of controlling a liquid metal circuit device by providing a liquid metal receptor in which a microchannel for a liquid circuit is formed and an electrode portion for connecting the liquid circuit to the outside and by compensating for a difference in thermal expansion volume between the microchannel and the liquid metal according to a change in temperature using a liquid metal supply portion that exchanges the liquid metal through the microchannel.

Also, Patent Document 4 provides a non-sintered liquid metal ink fabricating method that may fabricate liquid metal nanoparticles into ink using an ultrasonic spray and may fabricate an electrode through a solution process.

Patent Document 5 relates to a stretchable electrode circuit capable of performing three-dimensional (3D) circuit printing, a strain sensor using the same, and a fabricating method thereof, and fabricates a liquid metal electrode by mixing formed liquid metal nanoparticles with a polymer matrix and by applying a 3D printing method.

However, in the case of using the polymer matrix, since there is an elastomer that serves as an insulator between liquid metal particles that are conductive elements, resistance is very high. To reduce the same and to apply to an existing device, an additional process is involved since a post-treatment process of removing the elastomer is required.

Also, since the electrode is made of a single bulk material, a theoretical increase in resistance may not be suppressed during stretching, which may lead to degrading a device performance.

Therefore, although a liquid metal is an attractive material for stretchable electronic elements due to its high electrical conductivity and near-zero Young's modulus, the above arts have an issue in that an electrode forming process itself is performed in a solution-based and non-vacuum state and accordingly, has a very low incompatibility with current electronic element fabricating processes. In particular, since high surface tension of the liquid metal makes it difficult to form a film, there are no reports yet on thin-film electrodes using the liquid metal.

Accordingly, as a result of making efforts to solve the issues found in the art, the inventors of the present application have completed the present invention by providing a thin-film liquid metal electrode in which at least two types of liquid metal nanoclusters are sequentially over-layered with an oxide film in therebetween and deposited on a stretchable substrate in an over-layered structure using a liquid metal with excellent electrical conductivity and stretchability and a deposition method, by fabricating the thin-film liquid metal electrode in a structure in which at least two types of liquid metal nanoclusters are not in direct contact, and by generating an additional electrical path between two liquid metal networks as the thin film is ruptured due to mechanical deformation, thereby verifying negative piezoresistivity (NPR) property in which resistance decreases up to 85% during first 50% stretching.

Patent documents include (Patent Document 0001) Korean Patent No. 10-2052413 (announced on Jan. 8, 2020), (Patent Document 0002) Korean Patent Laid-Open Publication No. 10-2022-0014297 (published on Feb. 4, 2022), (Patent Document 0003) Korean Patent No. 10-1489900 (announced on Feb. 6, 2015), (Patent Document 0004) Korean Patent Laid-Open Publication No. 10-2022-0103028 (published on Jul. 21, 2022), and (Patent Document 0005) Korean Patent No. 10-2356658 (announced on Jan. 26, 2022).

### SUMMARY

An objective of the present invention is to provide a thin-film liquid metal electrode that implements negative piezoresistivity (NPR) in which resistance decreases during stretching.

Another objective of the present invention is to provide a method of fabricating a thin-film liquid metal electrode that may be controlled through a deposition method.

Another objective of the present invention is to provide a stretchable electronic element using a thin-film liquid metal electrode.

According to an aspect of the present invention, there is provided a thin-film liquid metal electrode, wherein at least two types of liquid metal nanoclusters are sequentially over-layered with an oxide film in therebetween and deposited as thin films on a stretchable substrate in an over-layered structure (or overlaid structure), and the at least two types of liquid metal nanoclusters are not in direct contact.

The stretchable substrate of the present invention is a surface-treated substrate and the surface-treatment may change surface energy and may control size and sheet resistance of deposited liquid metal nanoclusters.

In the thin-film liquid metal electrode of the present invention, the at least two types of liquid metal nanoclusters are not in direct contact due to the oxide film and a conductive network is formed between the at least two types of liquid metal nanoclusters as the oxide film is ruptured. Here, the thin-film liquid metal electrode having the conductive network implements NPR in which resistance decreases during stretching and the NPR is implemented as reversible property.

Also, according to an aspect of the present invention, there is provided a method of fabricating a thin-film liquid metal electrode, the method including surface-treating a stretchable substrate; depositing liquid metal nanoclusters on the surface-treated stretchable substrate; forming an oxide film on the surface of the liquid metal nanoclusters through exposure to an oxygen environment after the deposition; and sequentially depositing different types of liquid metal nanoclusters on the formed oxide film.

Also, according to an aspect of the present invention, there is provided a stretchable electronic element using a thin-film liquid metal electrode.

The thin-film liquid metal electrode may be applied to an interconnect wiring, a strain sensor, and a stretchable heater.

Also, according to an aspect of the present invention, there is provided a stretchable electronic device applied to one selected from a group including a solar cell, a display, and a biosensor using the stretchable electronic element including the thin-film liquid metal electrode.

A thin-film liquid metal electrode according to some example embodiments of the present invention may configure at least two types of liquid metal nanoclusters that do not mix with each other due to the intentionally oxidized interface of an oxide film as an over-layered structure in which the at least types of liquid metal nanoclusters are sequentially over-layered with the oxide film in between on a stretchable substrate and may generate an additional electrical path between two metal networks due to mechanical deformation.

Therefore, as the oxide film that exhibits an insulating effect is ruptured due to the mechanical deformation, liquid eutectic gallium indium (EGaln) may be formed and an additional conductive path may be formed, resulting in gigantic negative piezoresistivity (G-NPR) property in which resistance decreases during stretching.

Since a thin-film liquid metal electrode of the present invention is fabricated using a deposition method, post-treatment processes, such as a conventional solution process, a heat treatment, and an elastomer removal, are excluded and the electrode is fabricated using a deposition process employed in a conventional semiconductor process, so process compatibility is very high.

Also, while a liquid metal fabricated using a conventional syringe has limitations in forming a thickness and a pattern according to a micro to millimeter-sized nozzle, a thin-film liquid metal electrode fabricated with a deposition method of the present invention may have a line width with a desired high resolution using photolithography and metal mask.

Also, due to G-NPR property implemented by a thin-film liquid metal electrode of the present invention, it may be usefully applied to a stretchable electronic device by decreasing resistance up to 85% during first 50% stretching.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a flowchart for explaining a fabricating process of a thin-film liquid metal electrode using a deposition method of the present invention;

FIG. 2 illustrates scanning electron microscopy (SEM) images of an indium/oxide/gallium (InOG) electrode in an over-layered structure that is an implementation of a thin-film liquid meta electrode of the present invention;

FIG. 3 illustrates SEM images of a single indium (In) metal, a single gallium (Ga) metal, and eutectic gallium indium (EGaln) and In/lGa films without an oxide film member;

FIG. 4 illustrates scanning electron microscopy and energy dispersive spectroscopy (SEM-EDS) images for In, EGaln, In/Ga films, and In/oxide/Ga;

FIG. 5 illustrates SEM results for surface for each InOG electrode fabricated with various liquid metal thicknesses according to an example embodiment of the present invention;

FIG. 6 illustrates a surface image of single In metal or InoG electrode according to plasma treatment conditions of the present invention;

FIG. 7 illustrates results of a change in sheet resistance according to a change in surface energy of a substrate, size of In nanoclusters, and size of Ga nanoclusters, for various plasma treatment conditions of the present invention;

FIG. 8 illustrates current-voltage (I-V) property of an InOG electrode that is an implementation of the present invention;

FIG. 9 illustrates X-ray photoelectron spectroscopy (XPS) spectrum results of an indium oxide film formed due to air exposure in a fabricating method of the present invention;

FIG. 10 illustrates results of a change in relative resistance of an InOG electrode during first stretching (Rₛ, 1) for various metal thicknesses, for the InOG electrode that is an implementation of the present invention;

FIG. 11 illustrates a stretching mechanism of an InOG electrode that is an implementation of the present invention;

FIG. 12 illustrates SEM surface images before and after stretching of an InOG electrode that is an implementation of the present invention;

FIG. 13 illustrates SEM results for real-time stretching of an InOG electrode that is an implementation of the present invention;

FIG. 14 is a graph showing mechanical reliability results of an InOG electrode through repeated stretch-release cycles for the InOG electrode that is an implementation of the present invention;

FIG. 15 is a graph showing fatigue test results of an InOG electrode after the test of FIG. 14;

FIG. 16 illustrates results of applying a photolithography method to an InOG electrode that is an implementation of the present invention;

FIG. 17 illustrates a change in reactivity of an InOG electrode that is an implementation of the present invention to a contact with an Al electrode;

FIG. 18 illustrates an example of applying a strain sensor using a thin-film liquid metal electrode of the present invention;

FIG. 19 illustrates an example of applying a sensitive sensor using a thin-film liquid metal electrode of the present invention; and

FIGS. 20 and 21 illustrate an example of application to a light emitting diode (LED) array using a thin-film liquid metal electrode of the present invention.

### DETAILED DESCRIPTION

Hereinafter, the present invention will be described.

The present invention provides a thin-film liquid metal electrode in which at least two types of liquid metal nanoclusters are sequentially over-layered with an oxide film in therebetween and deposited as thin films on a stretchable substrate in an over-layered structure and, here, the at least two types of liquid metal nanoclusters are not in direct contact.

In general, when fabricating an electrode using a liquid metal with excellent electrical conductivity and high stretchability, high surface tension of the liquid metal makes it difficult to form a film, but the present invention provides a thin-film liquid metal electrode using a thermal evaporation or a physical vapor deposition method.

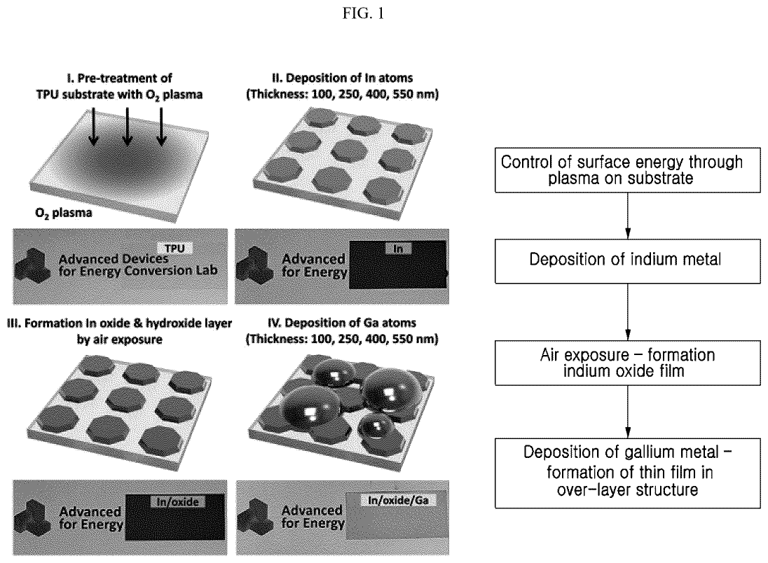

FIG. 1 is a flowchart for explaining a fabricating process of a thin-film liquid metal electrode using a deposition method of the present invention. In detail, the thin-film liquid metal electrode is provided by surface-treating a stretchable substrate, by depositing liquid metal nanoclusters on the surface-treated stretchable substrate, by forming an oxide film on the surface of the liquid metal nanoclusters through exposure to an oxygen environment after the deposition, and by sequentially depositing different types of liquid metal nanoclusters on the formed oxide film.

The thin-film liquid metal electrode of the present invention is in a structure in which at least two types of liquid metal nanoclusters are not in direct contact by way of the oxide film and, as the oxide film is ruptured due to mechanical deformation, a conductive network is formed between the at least two types of liquid metal nanoclusters.

The liquid metal used herein may use at least one selected from a gallium group present in a liquid state at room temperature or gallium-based alloys. For example, gallium, indium, and tin may be used.

A desirable implementation as the over-layered thin-film liquid metal electrode of the present invention may include one structure selected from a group including indium/oxide/gallium (InOG), gallium/oxide/indium (GaOI), tin/oxide/gallium (SnOG), and tin/oxide/indium (SnOI). The example embodiment of the present invention is described based on indium/oxide/gallium (InOG) as an example. However, without being limited thereto, the design may be modified with various combinations by selecting from the room-temperature liquid metal group.

The at least two types of liquid metal nanoclusters may be formed by depositing thin films of the same thickness or different thicknesses.

Desirably, each of the at least two types of liquid metals (or liquid metal nanoclusters) is deposited under control with a nanoscale thickness and, for the InOG electrode, the example embodiment of the present invention fabricates In and Ga metals to have the same thickness or different thicknesses by controlling thicknesses thereof within the range of 100 to 550 nm. However, without being limited thereto, any electrodes fabricated with a thickness within the nanoscale range may be included in the scope of the present invention.

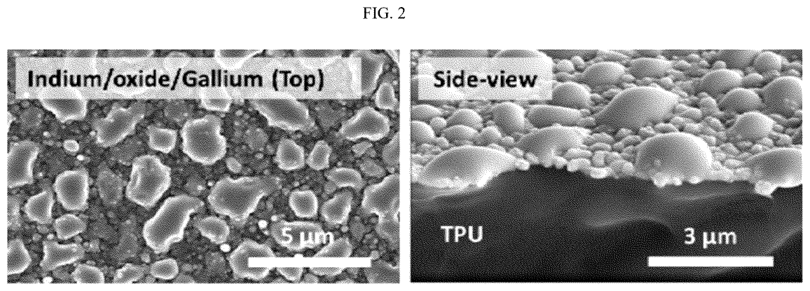

FIG. 2 illustrates scanning electron microscopy (SEM) images of an InOG electrode in an over-layered structure that is an implementation of a thin-film liquid metal electrode of the present invention. Here, in the InOG electrode, larger gallium (Ga) clusters seem to cover indium (In) clusters smoothly.

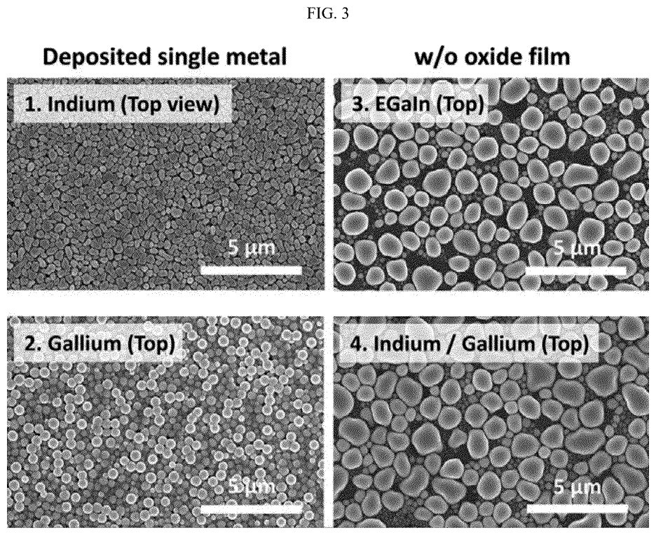

FIG. 3 illustrates SEM images of a single In metal, a single Ga metal, and eutectic gallium indium (EGaln) and In/Ga films without an oxide film member. Here, deposited single metals, In and Ga, or EGaln and In/Ga films without the oxide film, are shown to form isolated nanoclusters due to their high surface energy.

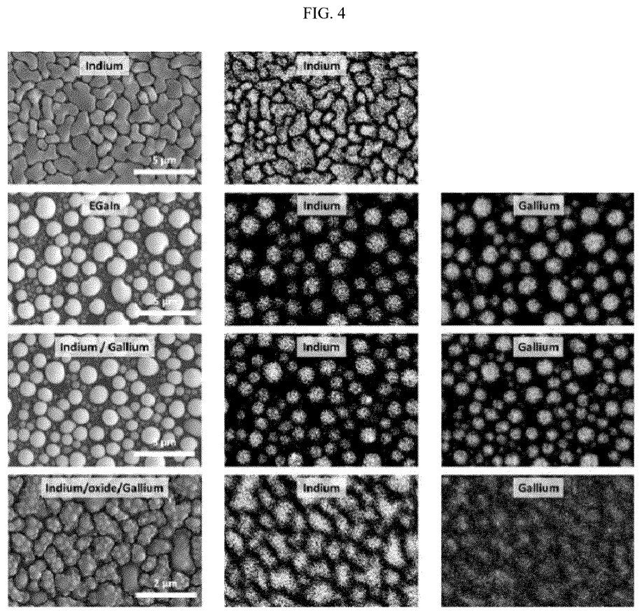

Scanning electron microscopy and energy dispersive spectroscopy (SEM-EDS) image results for In, EGaIn, In/Ga, and In/oxide/Ga of FIG. 4 show a method in which In and Ga atoms are arranged through a formation process and, here, In/Ga films sequentially deposited without the oxide film appear similar to EGaIn, suggesting that both metals are solid solution to each other and transform to EGalm immediately (Hume-Rothery theory).

On the contrary, in the InOG electrode on which the oxide film of the present invention is formed, it can be seen that In clusters are formed in an over-layered structure in which the In clusters are covered with much larger Ga clusters due to wettability by the oxide film intentionally formed on the In surface. Here, controlling the wettability is very important to fabricate a highly conductive liquid metal film and the wettability of a liquid metal may be improved by increasing the surface energy of a substrate through surface treatment of the substrate.

The surface treatment of the substrate may be performed through selection from among oxygen plasma treatment, ultraviolet treatment, and ozone treatment. The example embodiment of the present invention makes a description based on the oxygen plasma treatment, but is not limited thereto.

Although the example embodiment of the present invention makes a description using thermoplastic polyurethane (TPU), at least one selected from a group including thermoplastic or thermosetting copolymer, polydimethylsiloxane (PDMS), acrylic foam tape (AFT), silicone elastomer, polyimide, polyethylene Isopthalate, polyethylene naphthalate, polyethylene terephthalate, cellulose, shape memory polymer, and hydrogel may be selected and used.

More desirably, the present invention may use a surface-treated stretchable substrate for the stretchable substrate.

In detail, a change in the surface energy through the surface treatment may be calculated by applying an extended Fowkes model using contact angles obtained under polar and non-polar solvent conditions. It can be seen that the surface energy of a pristine TPU according to an example embodiment is 47.8 mJ/m², exhibiting the increase to 68.8 and 79.7 mJ/m² under oxygen plasma treatment conditions, 40 W and 2 minutes (min) and 90 W and 5 min, respectively (see Table 2).

That is, the increase in the surface energy of the TPU substrate represents the increase in wettability and the liquid metal forms larger nanoclusters and accordingly, forms a thin film on the substrate.

Therefore, the InOG electrode of the present invention is formed on the substrate with the increased wettability after the surface treatment and as the oxygen plasma intensity increases, the size of formed liquid metal nanoclusters increases due to the improved wettability. As an example, the average size of initial In nanoclusters (thickness: 100 nm) and that of Ga nanoclusters (thickness: 100 nm) increased from 208 to 263 nm and from 132 to 421 nm, respectively.

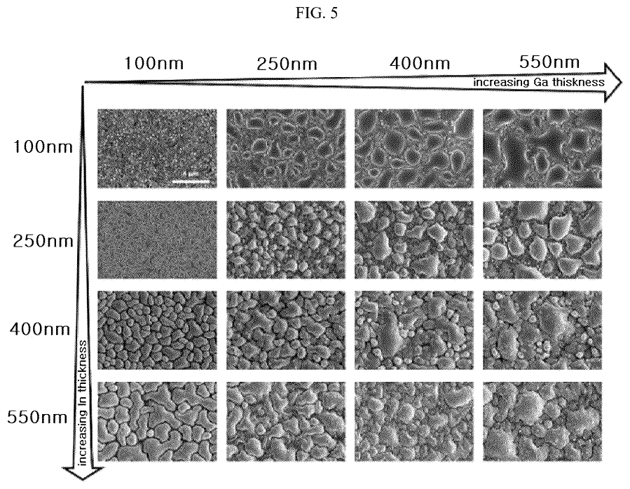

FIG. 5 illustrates SEM results for surface for each InOG electrode fabricated with various liquid metal thicknesses according to an example embodiment of the present invention. It can be seen that the size of nanoclusters tends to increase according to an increase in the thickness of In and Ga.

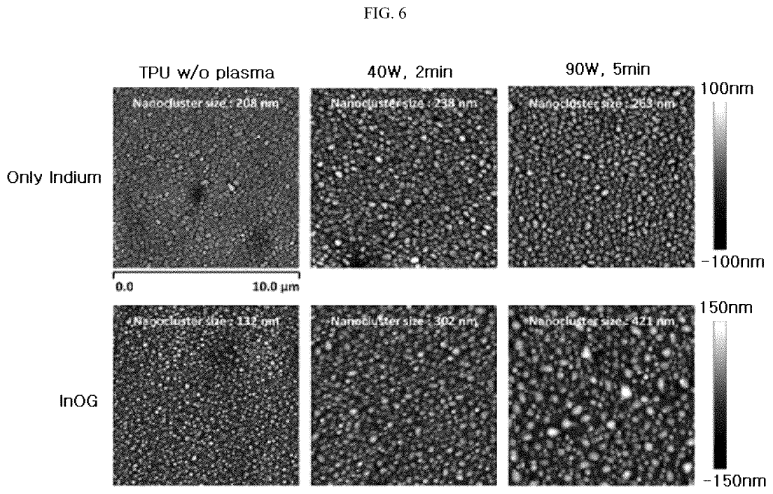

FIG. 6 illustrates a surface image of single In metal or InoG electrode according to plasma treatment conditions of the present invention. Here, the metal size increases with plasma treatment compared to a case without plasma treatment. In particular, the significant change in the size can be seen in the case of the InOG electrode.

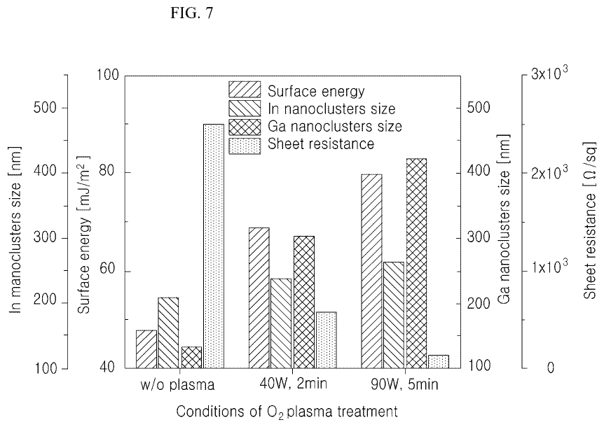

FIG. 7 illustrates results of a change in sheet resistance according to a change in surface energy of a substrate, size of In nanoclusters, and size of Ga nanoclusters, for plasma treatment conditions of the present invention. Here, the increase in the size of In and Ga nanoclusters according to plasma treatment conditions shows a decrease in sheet resistance. In detail, under plasma treatment conditions of 90 W and 5 min, the sheet resistance decreases from ˜2500 Ω/sq to 137.9 Ω/sq.

Therefore, the present invention may change the surface energy of the substrate and may control the size and the sheet resistance of deposited metal nanoclusters through plasma treatment of the substrate.

That is, as the surface energy improves through the plasma treatment of the substrate, bonding force of the liquid metal to the substrate also improves and accordingly, the thin-film liquid metal electrode tends to widely spread, which leads to increasing the size of nanoclusters. Such size increase allows wider nanoclusters to form an over-layer, decreasing the sheet resistance. Since a cross-sectional area in which two metal nanoclusters are in contact is a conductive path, a combination of larger nanoclusters increases a contact area itself, allowing electrons to flow much better.

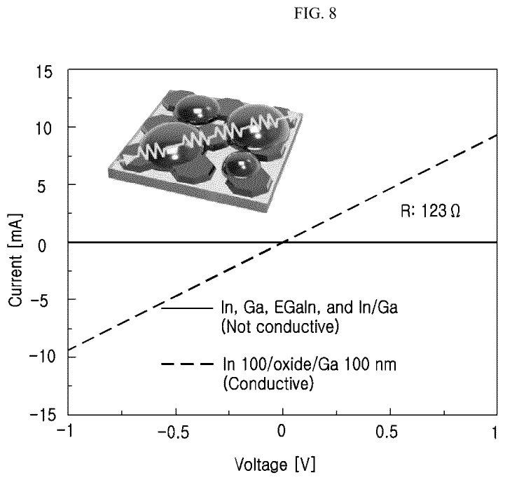

FIG. 8 illustrates current-voltage (I-V) property of an InOG electrode of the present invention. Here, when In and Ga are alone (In, Ga) or when In and Ga are morphologically separated from each other (EGaln and In/Ga film), there is no conductivity. However, it can be seen that the InOG electrode of the present invention with the oxide film exhibits conductivity. Therefore, it can be confirmed that the InOG electrode of the present invention is in an over-layered structure in which Ga clusters widely cover In clusters due to wettability by the In oxide film, rather than a single or a morphologically separated structure.

In the thin-film liquid metal electrode of the present invention, the oxide film refers to an intentionally oxidized interface and is not limited to exposure to air or an artificial formation method.

Also, the oxide film refers to a natural oxide film formed with a thickness of 3 nm or less and In and Ga of the InOG electrode are not in direct contact due to insulating property of the oxide film.

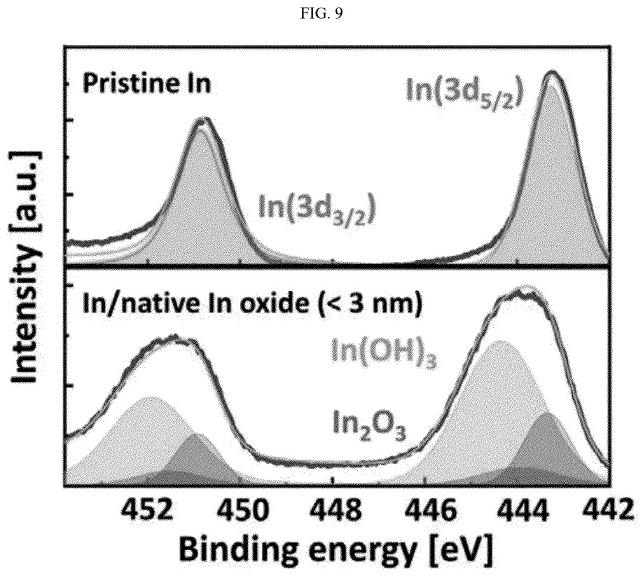

FIG. 9 illustrates X-ray photoelectron spectroscopy (XPS) spectrum results of an indium oxide film formed due to air exposure in a fabricating method of the present invention. Here, it can be seen that In oxide materials, In₂O₃ and In(OH)₃, inducing conductivity are formed in the InOG electrode.

The thin-film liquid metal electrode of the present invention is in a structure in which at least two types of liquid metal nanoclusters are not in direct contact and as the oxide film is ruptured due to mechanical deformation, a conductive network is formed between the at least two types of liquid metal nanoclusters. Here, the thin-film liquid metal electrode having the conductive network implements negative piezoresistivity (NPR) in which resistance decreases during stretching.

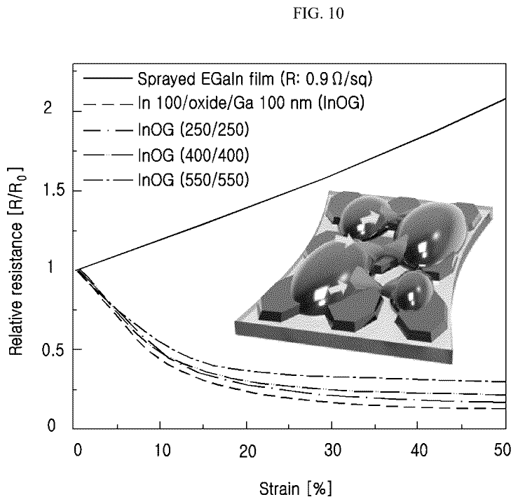

FIG. 10 illustrates a change in relative resistance of an InOG electrode during first stretching (Rₛ, 1) for various metal thicknesses, for the InOG electrode that is an implementation of the present invention. While the conventional sprayed EGaIn film exhibits positive piezoresistivity (PPR), the InOG electrode of the present invention exhibits gigantic negative piezoresistivity (G-NPR) property in which resistance decreases during stretching, for example, the resistance decreases up to 85% during first 50% stretching.

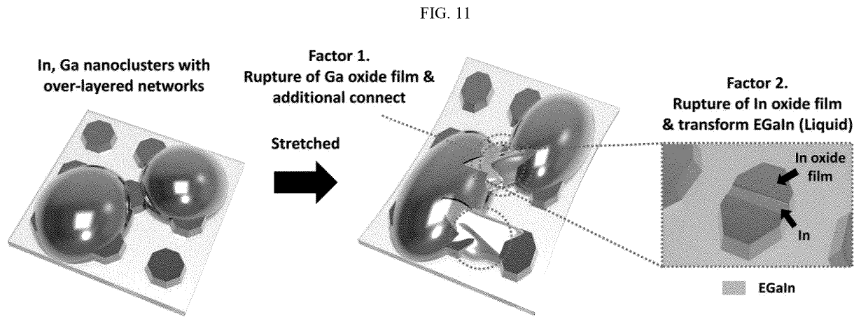

As shown in FIG. 11, the G-NPR property of the InOG electrode that is an implementation of the present invention may be explained as a factor of decreasing contact resistance since 1) an additional electrical path is formed as the oxide film that exhibits the insulating effect is ruptured or 2) EGaIn is formed due to spontaneous reaction as the In oxide film is ruptured. When both cases are implemented, the NPR property becomes larger during stretching.

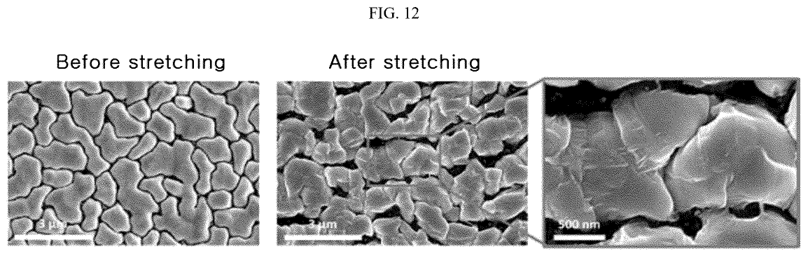

FIG. 12 illustrates SEM surface images before and after stretching of an InOG electrode that is an implementation of the present invention. In general, the EGaIn is thermodynamically spontaneously formed through direct contact of In and Ga.

However, although immediate formation of EGaln does not occur in the InOG electrode of the present invention due to the oxide film, rupture of the In oxide film by mechanical transformation (stretching) and spontaneous transformation of In and Ga into EGaIn by virtue of an endothermic reaction are verified through a morphological change. Therefore, during the transformation of In and Ga into EGaln, In—O is dissociated and the dissociated oxygen forms oxide on the surface by Ga oxide having a higher oxygen reactivity.

The results are confirmed from x-ray diffraction (XRD) analysis results. As a result of measuring In, Ga, EGaIn, pristine In/oxide/Ga, and stretched In/oxide/Ga, not-stretched In/oxide/Ga films include only In and Ga peaks and do not form EGaIn alloys due to the oxide film and In and Ga peaks and wide EGaIn peaks are all observed from the stretched In/oxide/Ga (not shown).

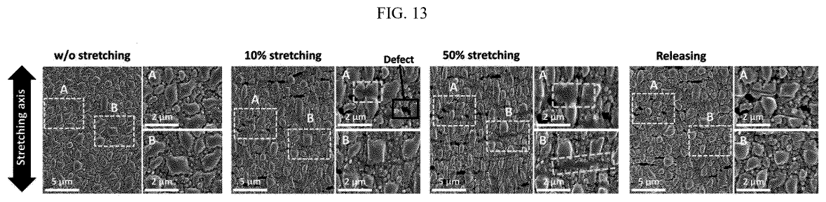

FIG. 13 illustrates SEM results for real-time stretching of an InOG electrode that is an implementation of the present invention, and shows results of observing points A and B from a released (not-stretched) electrode and observing the surface under 10% stretching and 50% stretching conditions and released state.

Under the 10% stretching condition, a surface defect (point A, solid-lined box) occurs and a rupture occurs in the oxide film on the surface of In nanoclusters at point A in a direction perpendicular to a stretching axis. Here, after the rupture of the oxide film, the liquid metal leaks from the inside and is connected to surrounding Ga nanoclusters and this connection of nanoclusters forms an additional electrical path (point A, dotted-lined box). During 50% stretching, a rupture of the oxide film and an additional connection are observed at point B. This connection is maintained due to irreversible deformation of the liquid metal after release and this deformation decreases resistance after the first stretching. That is, after the first stretching, a void ratio is largely reduced to 10 to 40 since the void is filled by liquid EGaIn that is formed by the rupture of the In oxide film. The void ratio is noticeably smaller in the electrode with lower sheet resistance and stretching significantly reduces the void ratio in a thicker film since the void of the film is quickly filled by the leaked liquid metal. Therefore, the cross-section of the stretched InOG electrode represents that physical vacancy between In islands is largely filled. A secondary NPR rate (0.1 to 0.2) is smaller than a primary NPR rate (0.7 to 0.9) as the void ratio decreases.

Also, the thin-film liquid metal electrode of the present invention implements the NPR as reversible property.

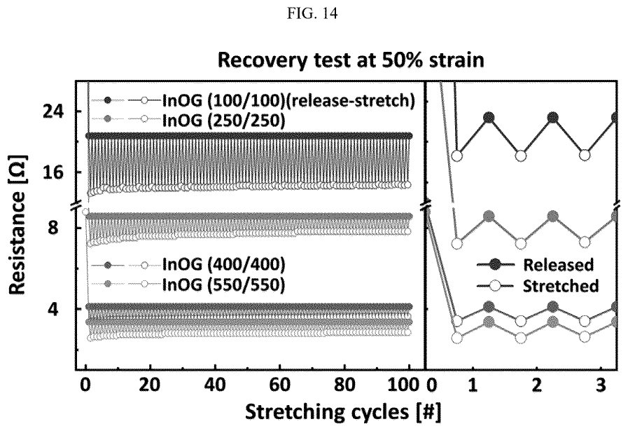

FIG. 14 is a graph showing mechanical reliability results of an InOG electrode through repeated stretch-release cycles for the InOG electrode that is an implementation of the present invention. As a result of performing stretch-release for during 100 cycles with 50% strain after the first stretching, all InOG electrodes of embodiments 1 to 4 exhibit reversible NPR property and excellent resistance recovery. The reversible NPR property is a specific property that is not observed in bulk-type conductors and other liquid metal campsites that exhibit a primary NPR effect.

The reversible NPR property is caused by a merged area between the liquid metal nanoclusters that reversibly vary during stretching cycles and the merged area (i.e., electrical path) increases by stretching, decreasing resistance. However, upon release, the nanoclusters return to their original state and the merged area decreases, increasing the resistance.

While the first G-NPR is a result of permanent connection between nanoclusters and reduced contact resistance, NPR in subsequent cycles is caused by reversibly varying areas between the connected nanoclusters. Although relative resistance of NPR in a cycle test is not as large as that of the first G-NPR, the unique property of InOG is maintained during 100 cycles of a recovery test.

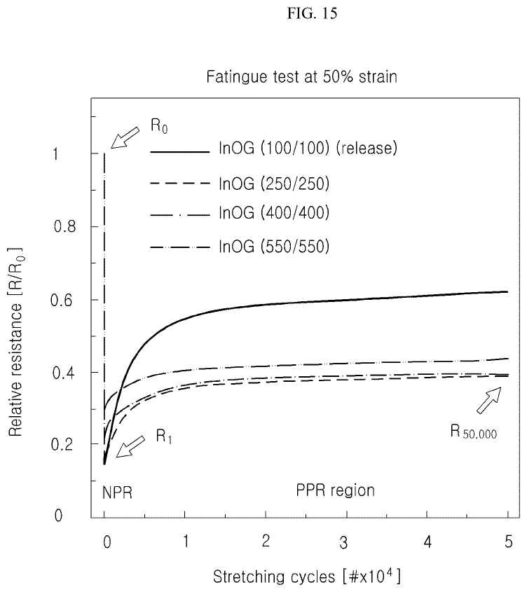

FIG. 15 is a graph showing fatigue test results of an InOG electrode after the test of FIG. 14. The resistance of the InOG released through stretch-release cycles continued to increase during 50,000 fatigue test cycles, and the final resistance of R₅₀₀₀₀ increased 4-fold compared to that of R₁. Nevertheless, R₅₀₀₀₀ was lower than that of an initial film (R₀) and a thicker film exhibits high mechanical stability with a smaller resistance change.

Also, the present invention provides a stretchable electronic element using the thin-film liquid metal electrode.

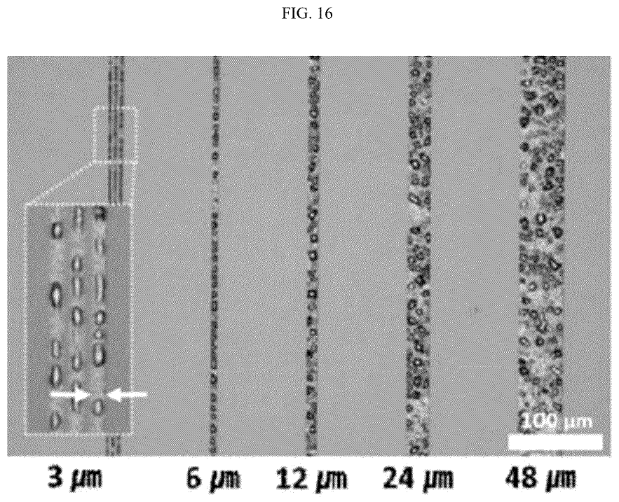

FIG. 16 illustrates results of applying a photolithography method to an InOG electrode that is an implementation of the present invention. Since a line width with a high resolution (minimum 3 μm) may be fabricated, compatibility with photolithography for mass production of electronic components is excellent.

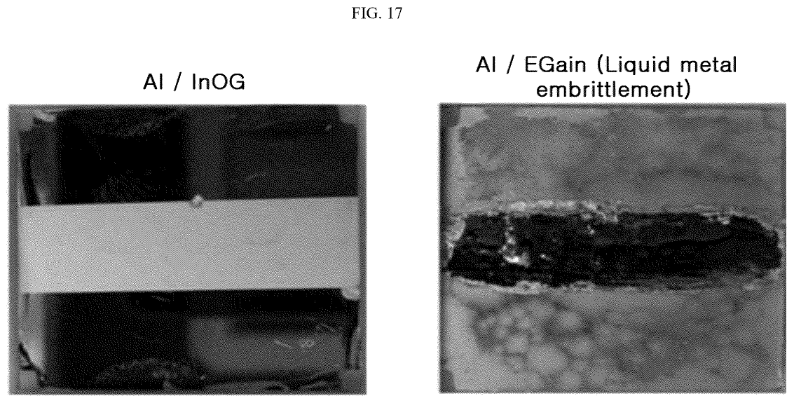

FIG. 17 illustrates a change in reactivity of an InOG electrode of the present invention to a contact with an Al electrode. When Al/EGaln were in contact, embrittlement occurred at contact interface with aluminum, whereas Al/InOG showed a clean surface.

The occurrence of the embrittlement represents an electrode rupture. Since the present invention prevents a direct contact between Ga of InOG and AI using an In layer, the InOG electrode is stable. Therefore, this indicates that the InOG may be harmoniously hybridized with conventional materials.

Accordingly, the thin-film liquid metal electrode of the present invention has excellent compatibility with conventional electronic components and is stable without the embrittlement with the contact electrode and thus, may be useful as a stretchable electronic element.

As a desirable example, the present invention may be applied to an interconnect wiring, a strain sensor, and a stretchable heater.

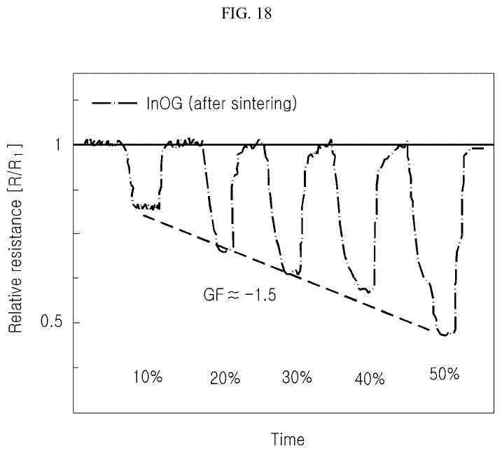

FIG. 18 illustrates results of measuring relative resistance for a series of strains from 10 to 50% by stepwise stretching of an InOG electrode of the present invention after sintering. Here, the InOG electrode exhibits a uniform gauge factor (about −1.5) and thus, is suitable for use as a strain gauge.

Also, the present invention may provide a stretchable electronic device applied to one selected from a group including a solar cell, a display, and a biosensor using the stretchable electronic device using the thin-film liquid metal electrode.

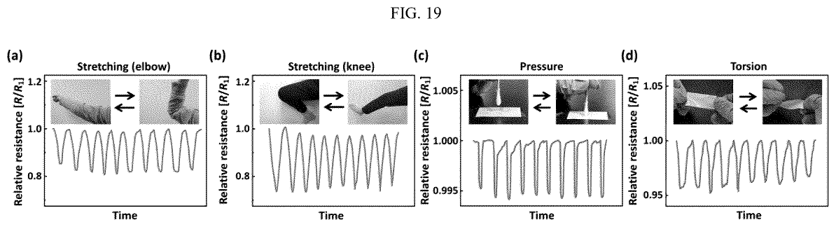

As a detailed example, FIG. 19 illustrates an example of applying a sensitive sensor using a thin-film liquid metal electrode of the present invention. Here, (a) shows relative resistance after sintering when the InOG electrode is applied to an elbow of a human body and (b) shows relative resistance after sintering when the InOG electrode is applied to a knee of the human body.

Upon bending the elbow and the knee, resistance decreases. Here, knee bending shows a larger change in relative resistance (|ΔR|/R₁=0.27) than that of elbow bending (|ΔR|/R₁=0.19). Also, the InOG electrode detects (c) pressure and (d) torsion as similar tendency, which supports applicability of the InOG electrode to the stretchable electronic device.

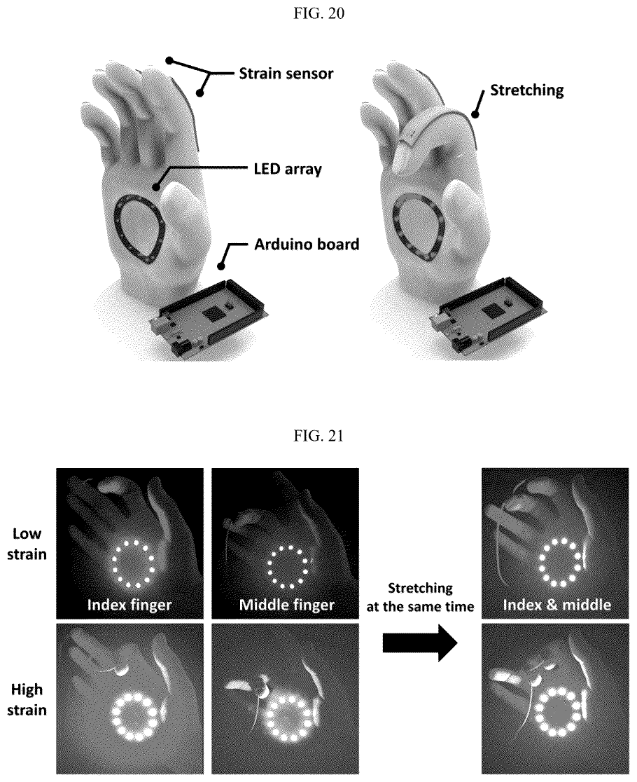

As an example of applying a stretchable electronic device using a thin-film liquid metal electrode of the present invention, FIG. 20 illustrates an implementation example of application to a light emitting diode (LED) array, and FIG. 21 illustrates an image captured from a change in light intensity according to a degree of bending fingers. In detail, an InGO film with NPR property is attached to index and middle fingers and applied to an LED array regulated by applied strain using an Arduino board. Here, various strains may be applied by connecting the index and middle fingers to a red LED (e.g., index finger) and a blue LED (e.g., middle finger), respectively, by allowing each of the LEDs to emit low (high) intensity light at low (high) strain, and by adjusting the degree of bending fingers.

Hereinafter, the present invention will be further described through embodiments and comparative examples.

The following embodiments are provided as examples only to describe the present invention and not construed as limiting the present invention.

### <Embodiments 1 to 16> InOG Electrode Fabrication Per Liquid Metal Thickness

Initially, a thermoplastic polyurethane (TPU) substrate (3 cm×2 cm) was cleaned with isopropyl alcohol (IPA) for 1 min in an ultrasonic cleaner. O₂ plasma was used to treat the precleaned TPU substrate at 90 W for 5 min. Indium was deposited onto the O₂ plasma-treated TPU substrate using high vacuum (10⁻⁷ Torr) thermal evaporation and In nanoclusters were fabricated for each thickness (100 to 550 nm). The TPU film on which the In nanoclusters were deposited was exposed to air for 10 seconds and a think native indium oxide and indium hydroxide layer was formed on the surface of In. Subsequently, the InOG electrode was fabricated by returning the substrate to a vacuum deposition chamber and by depositing Ga nanoclusters onto the TPU/In/In oxide film for each thickness (100 to 550 nm). The In nanoclusters were deposited with thickness of 100, 250, 400, 550 nm and Ga nanoclusters were deposited with thickness of 100, 250, 400, 550 nm. Here, the InOG electrodes of Embodiments 1 to 16 were fabricated by depositing the different types of liquid metal nanoclusters with the same thickness or different thicknesses.

Hereinafter, the property of the InOG electrode is described based on Embodiments 1 to 4 shown in Table 1 below.

TABLE 1

| | Thickness of In | Thickness of Ga nanoclusters, |
|---|---|---|
| | nanoclusters, nm | nm |
| Embodiment 1 | 100 | 100 |
| Embodiment 2 | 250 | 250 |
| Embodiment 3 | 400 | 400 |
| Embodiment 4 | 550 | 550 |

### <Embodiment 17> InOG Electrode Fabrication for Each Surface Treatment Condition of Substrate

The InOG electrode was fabricated in the same manner as in Embodiment 1, except that the TPU substrate was treated with O₂ plasma at 40 W for 2 min.

### <Experimental Example 1> Surface Evaluation of Surface Treatment of Substrate

### 1. Measurement of Surface Energy

The O₂ plasma treatment condition for the TPU substrate and surface property according thereto are listed in the following Table 2. Here, the surface energy was calculated by applying the extended Fowkes model using each of contact angles obtained under polar and nonpolar solvent conditions for a surface property value.

TABLE 2

| | | | | Surface energy | | |
|---|---|---|---|---|---|---|
| | | Contact angle | | Polar | | |
| | | | Non- | surface | Dispersive | |
| | | Polar | polar | energy, | energy, | Sum, |
| | Condition | solvent | solvent | mJ/m² | mJ/m² | mJ/m² |
| Comparative | O₂ plasma | 76° | 31° | 4 | 43.8 | 47.8 |
| example 1 | non- | | | | | |
| | treatment | | | | | |
| Embodiment | 40 W, | 35° | 28° | 23.9 | 44.9 | 68.8 |
| 17 | 2 min | | | | | |
| Embodiment | 90 W, | 8° | 17° | 31.1 | 48.6 | 79.7 |
| 1 | 5 min | | | | | |

Polar solvent: water, non-polar solvent: diiodo-methane

As shown in Table 2, results of the surface energy using contact angles obtained under polar and non-polar solvents show that the surface energy of pristine TPU was 47.8 mJ/m², which increased to 68.8 and 79.7 mJ/m² under 40 W, 2 min (Embodiment 17) and 90 W, 5 min (Embodiment 1), respectively.

Therefore, since an increase in the surface energy represents an increase in wettability, the hydrophilic In oxide film according to O₂ plasma treatment improved the low wettability of Ga on In. In this stage, In and Ga may not form EGaln immediately since the oxide film on the surface prevents a direct contact with the metal. Ga nanoclusters serve as an electrical bridge between In nanoclusters to form an electrical path.

### 2. Measurement of Surface Morphology

The surface of single In or InOG electrode under the plasma treatment conditions was measured using an atomic force microscope (AFM) and surface image results are shown in FIG. 4.

As a result, the size of metal nanoclusters formed on the TPU substrate increased according to plasma treatment, more desirably, plasma treatment conditions. Under the same plasma conditions, the size of nanoclusters on the surface of the InOG electrode relatively increased.

Also, FIG. 6 illustrates SEM results for the surface of each InOG electrode fabricated for each liquid metal thickness according to an example embodiment. Also, when forming the InOG electrode using a deposition method in addition to Embodiments 1 to 4 of the present invention, different types of liquid metal nanoclusters may be formed on the surface of the InOG electrode with the same thickness or different thicknesses.

### <Experimental Example 2> Electrical Property of InOG Electrode

For the InOG electrode fabricated according to Embodiment 1, sheet resistance was measured using a 4-point probe (FPP-2400, Dasol Eng., South Korea). I-V curves of the electrode were measured using a Keithley source meter (Tektronix, USA).

FIG. 7 illustrates results of a change in sheet resistance according to a change in surface energy of a substrate, size of In nanoclusters, and size of Ga nanoclusters, for various plasma treatment conditions of the present invention. An increase in the sizes of In and Ga nanoclusters according to the plasma treatment conditions shows a decrease in sheet resistance and the sheet resistance decreased from ˜2500 Ω/sq to 137.9 Ω/sq under the plasma treatment condition, 90 W, 5 min.

FIG. 8 illustrates current-voltage (I-V) property of an InOG electrode of the present invention. The electrode according to Embodiment 1 (In 100 nm/oxide/Ga 100 nm) has electrical conductivity (line resistance: 123 Φ) through an electrical bridge induced by Ga on In clusters, but In only (100 nm), Ga only (550 nm), EGaIn (650 nm), and In/Ga (650 nm) films were not conductive since each liquid metal was alone or they were morphologically disconnected from each other. In Embodiment 1, it can be verified that In and Ga are formed in an over-layered structure.

### <Experimental Example 3> X-Ray Analysis of Indium Oxide Film

For the InOG electrode fabricated according to the example embodiment, X-ray photoelectron spectroscopy (K-alpha, Thermo VG Scientific) was performed to measure In 3d and Ga 3d intensities using binding energy.

As a result, as illustrated in FIG. 9, XPS data was obtained for pristine In and In/oxide samples, and pristine In was prepared by depositing Au (15 nm) thereon to prevent further oxidation. In XPS spectrum of In 3d3/2, spin-orbit splitting peaks of In 3d showed an interval of 7.3 eV between In 3d3/2 and In 3d5/2. In the case of In metal (450.8 eV), In₂O₃ (451.4 eV), and In(OH)₃ (452.4 eV), in nanoclusters, In₂O₃ and In(OH)₃ were oxidized under ambient conditions for a few seconds as In₂O₃ and In(OH)₃ by O₂ and vapor and only In/oxide revealed peaks of In/oxide peaks (blue, the lowest peaks).

### <Experimental Example 4> Piezoresistivity Property of InOG Electrode

For the InOG electrodes fabricated according to Embodiments 1 to 4, a change in relative resistance of the InOG electrodes during the first stretching (Rₛ, 1) was measured for various thicknesses.

As illustrated in FIG. 10, as an example of a conventional method, measurement for a sprayed EGaIn film (thickness: 3 μm, R: 0.9 Ω/sq) shows positive piezoresistivity (PPR). In contrast, the InOG electrodes fabricated according to Embodiments 1 to 4 show a significant difference by exhibiting gigantic negative piezoresistivity (G-NPR). Here, the present invention defines an NPR rate as a resistance change ratio after n^{th} stretching by (R_{r,n-1}-R_{s,n})/R_{r,n-1}. Here, R_{s,n} and R_{r,n} are defined as a stretched and released condition state.

In detail, the InOG electrodes fabricated according to Embodiments 1 to 4 significantly decreased the resistance from the sheet resistance (R₀) to the resistance (Rₛ, 1) upon the first stretching. It is inferred that the tensile force sintered liquid metal nanoclusters and a new electrical path was formed.

Also, comparing Embodiment 1 (In 100/oxide/Ga 100 nm) and Embodiment 4 (In 550/oxide/Ga 550 nm), it can be verified that NPR property decreased for thick metals with relative resistance in 0.15 and 0.3, respectively.

This trend shows similar results in relative resistance measurement results for large strains up to 500%. In the case of Embodiments 1 and 2 in which a relatively thin thickness is used, a resistance value is still lower than the initial sheet resistance (R₀) even under 500% strain conditions. However, in the case of having a relatively thick thickness, conversion to PPR property was performed under 300% strain conditions.

Also, a void ratio of InOG continued to decrease from 250 to 100 by mainly increasing an In thickness from 100 nm to 550 nm, whereas Ga determined the sheet resistance of the film. A reduction in internal void occurred since the physical vacancy decreased by increasing a height and a width of clusters according to an increase in the In thickness, and the vacancy ratio decreased from 19.7% at 100 nm to 8.5% at 550 nm as observed from the In SEM images. Therefore, this reduction in the internal void lowered an NPR rate and Ga was deposited over a broad area and thus, determined the overall resistance.

Although the example embodiments of the present invention are described in detail, it will be apparent to those skilled in the art that various alterations and modifications may be made thereto within the technical scope of the present invention and such alternations and modification still fall within the scope of the claims.

What is claimed is:

1. A thin-film liquid metal electrode, wherein:
at least two types of liquid metal nanoclusters are sequentially over-layered with an oxide film in therebetween and deposited as thin films on a surface-treated stretchable substrate in an over-layered structure, and
the at least two types of liquid metal nanoclusters are not in direct contact.

2. The thin-film liquid metal electrode of claim 1, wherein a conductive network is formed between the at least two types of liquid metal nanoclusters as the oxide film is ruptured due to mechanical deformation.

3. The thin-film liquid metal electrode of claim 2, wherein the conductive network implements negative piezoresistivity (NPR) in which resistance decreases during stretching.

4. The thin-film liquid metal electrode of claim 3, wherein the NPR is implemented as reversible property.

5. The thin-film liquid metal electrode of claim 1, wherein the liquid metal includes at least one selected from a gallium group present in a liquid state at room temperature or gallium-based alloys.

6. The thin-film liquid metal electrode of claim 1, wherein the over-layered structure includes one selected from a group including indium/oxide/gallium (InOG), gallium/oxide/indium (GaOI), tin/oxide/gallium (SnOG), and tin/oxide/indium (SnOI).

7. The thin-film liquid metal electrode of claim 1, wherein the at least two types of liquid metal nanoclusters are deposited as thin films with the same thickness or different thicknesses.

8. The thin-film liquid metal electrode of claim 7, wherein each of the at least two types of liquid metal nanoclusters is deposited with a nanoscale thickness.

9. The thin-film liquid metal electrode of claim 1, wherein the oxide film is formed with a thickness of 3 nm or less.

10. The thin-film liquid metal electrode of claim 1, wherein the surface-treated stretchable substrate includes one selected from a group including thermoplastic polyurethane (TPU), thermoplastic or thermosetting copolymer, polydimethylsiloxane (PDMS), acrylic foam tape (AFT), silicone elastomer, polyimide, polyethylene isopthalate, polyethylene naphthalate, polyethylene terephthalate, cellulose, shape memory polymer, and hydrogel.

11. A method of fabricating a thin-film liquid metal electrode, the method comprising:
surface-treating a stretchable substrate;
depositing liquid metal nanoclusters on the surface-treated stretchable substrate;
forming an oxide film on the surface of the liquid metal nanoclusters through exposure to an oxygen environment after the deposition; and
sequentially depositing different types of liquid metal nanoclusters on the formed oxide film.

12. The method of claim 11, wherein the surface-treatment is performed through selection from among oxygen plasma treatment, ultraviolet treatment, and ozone treatment.

13. A stretchable electronic element using the thin-film liquid metal electrode of claim 1.

14. The stretchable electronic element of claim 13, wherein the thin-film liquid metal electrode is applied to an interconnect wiring, a strain sensor, and a stretchable heater.

15. A stretchable electronic device applied to one selected from a group including a solar cell, a display, and a biosensor using the stretchable electronic element including the thin-film liquid metal electrode of claim 13.
